(19) United States
(12) Patent Application Publication
(10) Pub. No.: US 2015/0180465 A1
(43) Pub. Date: Jun. 25, 2015

(54) RF SWITCH

(71) Applicant: SAMSUNG ELECTRO-MECHANICS CO., LTD., Suwon-Si (KR)

(72) Inventors: Yoo Sam NA, Suwon-Si (KR); Jong Myeong KIM, Suwon-Si (KR); Hyun Jin YOO, Suwon-Si (KR); Hyun Hwan YOO, Suwon-Si (KR); Yoo Hwan KIM, Suwon-Si (KR)

(73) Assignee: SAMSUNG ELECTRO-MECHANICS CO., LTD., Suwon-Si (KR)

(21) Appl. No.: 14/268,943

(22) Filed: May 2, 2014

(30) Foreign Application Priority Data
Dec. 20, 2013 (KR) 10-2013-0160518

(51) Int. Cl. H03K 17/16; H03K 17/687; H03K 17/689; H03K 17/605

(52) U.S. Cl. CPC H03K 17/162; H03K 17/16; H03K 17/605; H03K 17/6871; H03K 17/689

(57) ABSTRACT

A radio frequency (RF) switch may include: a common port; a first switching unit; and a second switching unit. The first switching unit further includes a third switching device having one end coupled to a body of one of the plurality of first switching devices and the other end coupled to a first ground terminal, and the second switching unit further includes a fourth switching device having one end coupled to a body of one of the plurality of second switching devices and the other end coupled to a second ground terminal.

### CROSS-REFERENCE TO RELATED APPLICATION

This application claims the benefit of Korean Patent Application No. 10-2013-0160518 filed on Dec. 20, 2013, with the Korean Intellectual Property Office, the disclosure of which is incorporated herein by reference.

### BACKGROUND

The present disclosure relates to a radio frequency (RF) switch.

Along with developments in wireless communications technologies, various communications standards have been simultaneously implemented. In addition, along with a trend for miniaturized wireless communications modules and high performance portable terminals, there has been a need for compliance with a plurality of communication standards in a single portable terminal. Thus, more frequency bands need to be supported by a single portable terminal.

That is, existing second-generation (2G) and third-generation (3G) communications technologies have been supplemented with new communications technologies, such that portable communications terminals compliant with fourth-generation (4G) communications schemes such as Long Term Evolution (LTE) have been developed. In addition, in the area of Wi-Fi communications, portable communications terminals have been implemented with the ability to operate with the IEEE 802.11ac standard in addition to the existing IEEE 802.11b/g/n to enhance marketability thereof.

In accordance with this trend, there has also been demand for support for various frequency bands within a radio frequency (RF) front end field. For example, support for various frequency bands with respect to an RF switch positioned on a signal path between an antenna and an RF chipset has been demand. Therefore, a Single Pole Double Throw (SPDT) type switch has been used in various applications.

Here, an RF switch requires low insertion loss characteristics, high power handling characteristics, and isolation characteristics. Particularly, the better the insertion loss characteristics, the lower the amounts of deterioration of a receiving unit and the transmission power loss of a transmitting unit that occur in the RF switch. In addition, the high power handling characteristics ensure a maximum output power of output power of the transmitting unit, and the isolation characteristics may significantly decrease an influence on the receiving unit turned off when the transmitting unit is operated.

However, in the case in which the RF switch is configured of only a metal oxide semiconductor field effect transistor (MOSFET), a size of the transistor is large, such that a parasitic capacitance component coupled to a gate may be present. Due to the parasitic capacitance component, a problem in which a high frequency signal may be output to an undesired port may occur.

The following Related Art Document (Patent Document 1), which relates to an RF switching circuit, discloses that a capacitor is coupled to a body in order to secure isolation characteristics. However, unlike the present disclosure, Patent Document 1 does not disclose that a ground terminal and at least one switching device are coupled to each other using a body bias in order to improve isolation characteristics.

### RELATED ART DOCUMENT

(Patent Document 1) Japanese Patent Laid-Open Publication No. 2011-228894

### SUMMARY

An aspect of the present disclosure may provide a radio frequency (RF) switch capable of improving isolation characteristics by coupling a body terminal of at least one of a plurality of switching devices configuring a transmitting unit or a receiving unit to a ground terminal.

According to an aspect of the present disclosure, an RF switch may include: a common port transmitting and receiving a high frequency signal; a first switching unit including a plurality of first switching devices coupled to each other in series and opening or blocking a signal transfer path between a first port to and from which the high frequency signal is input and output and the common port; and a second switching unit including a plurality of second switching devices coupled to each other in series and opening or blocking a signal transfer path between a second port to and from which the high frequency signal is input and output and the common port, wherein the first switching unit further includes a third switching device having one end coupled to a body of one of the plurality of first switching devices and the other end coupled to a first ground terminal, and the second switching unit further includes a fourth switching device having one end coupled to a body of one of the plurality of second switching devices and the other end coupled to a second ground terminal.

The third switching device may open or block a signal transfer path between the first ground terminal and the body of one of the plurality of first switching devices when the plurality of second switching devices open or block the signal transfer path between the second port and the common port, and the fourth switching device may open or block a signal transfer path between the second ground terminal and the body of one of the plurality of second switching devices when the plurality of first switching devices open or block the signal transfer path between the first port and the common port.

The third switching device may have one end coupled to a body of a first switching device disposed closely to the first port among the plurality of first switching devices and the other end coupled to the first ground terminal, and the fourth switching device may have one end coupled to a body of a second switching device disposed closely to the second port among the plurality of second switching devices and the other end coupled to the second ground terminal.

Each of the plurality of first switching devices and the fourth switching device may receive a first gate signal applied to a control terminal thereof to perform a switching operation, and each of the plurality of second switching devices and the third switching device may receive a second gate signal applied to a control terminal thereof to perform a switching operation.

The RF switch may further include: a first shunting unit coupled between the second port and the second switching unit to open or block a signal transfer path between the second port and a ground; and a second shunting unit coupled between the first port and the first switching unit to open or block a signal transfer path between the first port and a ground, wherein the first shunting unit includes a plurality of first switching devices coupled to each other in series, and the second shunting unit includes a plurality of second switching devices coupled to each other in series.

Each of the first switching devices and the second switching devices may be a field effect transistor (FET) or a bipolar junction transistor (BJT).

According to another aspect of the present disclosure, an RF switch may include: a transmitting switching unit including a plurality of first switch circuit units having first switching devices, respectively, and coupled to each other in series; and a receiving switching unit including a plurality of second switch circuit units having second switching devices, respectively, and coupled to each other in series, wherein each of the plurality of first switch circuit units further includes a first isolation unit including a third switching device having one end coupled to a body of the first switching device and the other end coupled to a ground, and each of the plurality of second switch circuit units further includes a second isolation unit including a fourth switching device having one end coupled to a body of the second switching device and the other end coupled to a ground.

The transmitting switching unit may receive a first gate signal applied to a control terminal of the first switching device included in each of the plurality of first switch circuit units to open or block a signal transfer path between a common port and a transmitting port, and the receiving switching unit may receive a second gate signal applied to a control terminal of the second switching device included in each of the plurality of second switch circuit units to open or block a signal transfer path between the common port and a receiving port.

Each of the first isolation units included in the plurality of first switch circuit units may receive the second gate signal applied thereto to open or block a signal transfer path between the ground and the body of each of the first switching devices, and each of the second isolation units included in the plurality of second switch circuit units may receive the first gate signal applied thereto to open or block a signal transfer path between the ground and the body of each of the second switching devices.

Each of the first switching devices and the second switching devices may be an FET or a BJT.

The RF switch may further include: a first shunting unit coupled between the receiving port and the receiving switching unit to open or block a signal transfer path between the receiving port and a ground; and a second shunting unit coupled between the transmitting port and the transmitting switching unit to open or block a signal transfer path between the transmitting port and a ground, wherein the first shunting unit includes a plurality of first switching devices coupled to each other in series, and the second shunting unit includes a plurality of second switching devices coupled to each other in series.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a radio frequency (RF) switch according to an exemplary embodiment of the present disclosure;

FIG. 2 is a circuit diagram illustrating the RF switch of FIG. 1 in more detail;

FIG. 3 is a view describing an operation of the RF switch according to an exemplary embodiment of the present disclosure;

FIG. 4 is a circuit diagram of the RF switch of FIG. 2 having shunting units added thereto;

FIG. 5 is a block diagram illustrating an RF switch according to another exemplary embodiment of the present disclosure;

FIG. 6 is a circuit diagram illustrating a transmitting switching unit in a configuration of the RF switch of FIG. 5 in more detail;

FIG. 7 is a circuit diagram illustrating a receiving switching unit in a configuration of the RF switch of FIG. 5 in more detail;

FIG. 8 is a circuit diagram illustrating the RF switch of FIG. 5 in more detail; and

FIG. 9 is a circuit diagram of the RF switch of FIG. 7 having shunting units added thereto.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

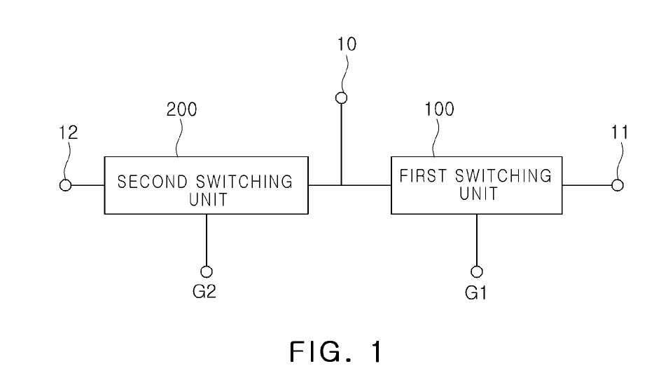

FIG. 1 is a block diagram illustrating a radio frequency (RF) switch according to an exemplary embodiment of the present disclosure.

Referring to FIG. 1, an RF switch according to an exemplary embodiment of the present disclosure may include a common port 10, a first switching unit 100, and a second switching unit 200.

The common port 10 may be coupled to an antenna to transmit and receive a high frequency signal.

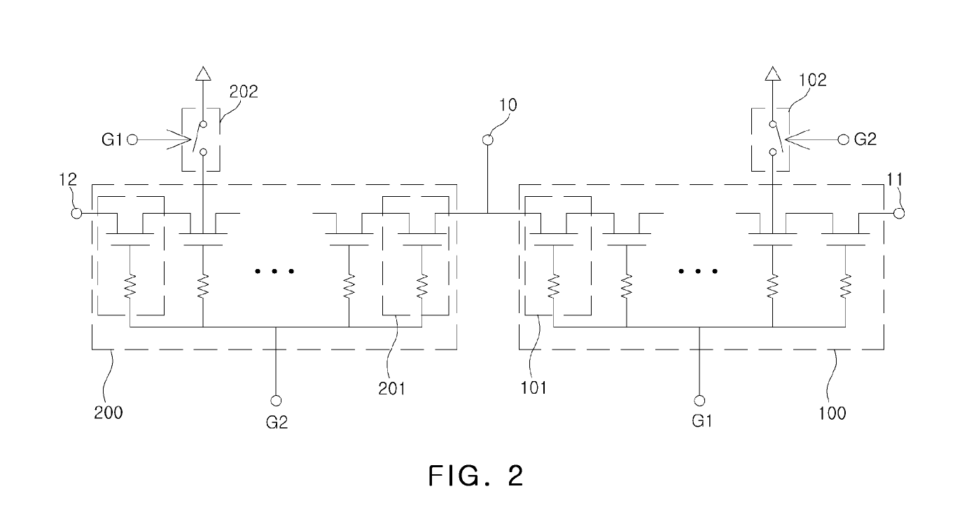

The first switching unit 100 may be coupled between the common port 10 and a first port 11 and may open or block a signal transfer path between the common port 10 and the first port 11. Meanwhile, the first switching unit 100 may include a plurality of first switching devices 101 (See FIG. 2) coupled to each other in series.

The second switching unit 200 may be coupled between the common port 10 and a second port 12 and may open or block a signal transfer path between the common port 10 and the second port 12. Meanwhile, the second switching unit 200 may include a plurality of second switching devices 201 (See FIG. 2) coupled to each other in series.

FIG. 2 is a circuit diagram illustrating the RF switch of FIG. 1 in more detail.

Referring to FIG. 2, the first switching unit 100 may include the plurality of first switching devices 101, wherein the plurality of first switching devices 101 may be coupled to each other in series. Here, one of the plurality of first switching devices may be coupled to a third switching device 102 having one end coupled to a body thereof and the other end coupled to a first ground terminal.

The second switching unit 200 may include the plurality of second switching devices 201, wherein the plurality of second switching devices 201 may be coupled to each other in series. Here, one of the plurality of second switching devices may be coupled to a fourth switching device 202 having one end coupled to a body thereof and the other end coupled to a second ground terminal.

Meanwhile, each of the plurality of first switching devices 101 included in the first switching unit 100 may receive a first gate signal G1 applied to a control terminal thereof to perform a switching operation. In addition, each of the plurality of second switching devices 201 included in the second switching unit 200 may receive a second gate signal G2 applied to a control terminal thereof to perform a switching operation.

In addition, the third switching device 102 may receive the second gate signal G2 applied thereto to open or block a signal transfer path between the body of one of the plurality of first switching devices and the first ground terminal. The fourth switching device 202 may receive the first gate signal G1 applied thereto to open or block a signal transfer path between the body of one of the plurality of second switching devices and the second ground terminal.

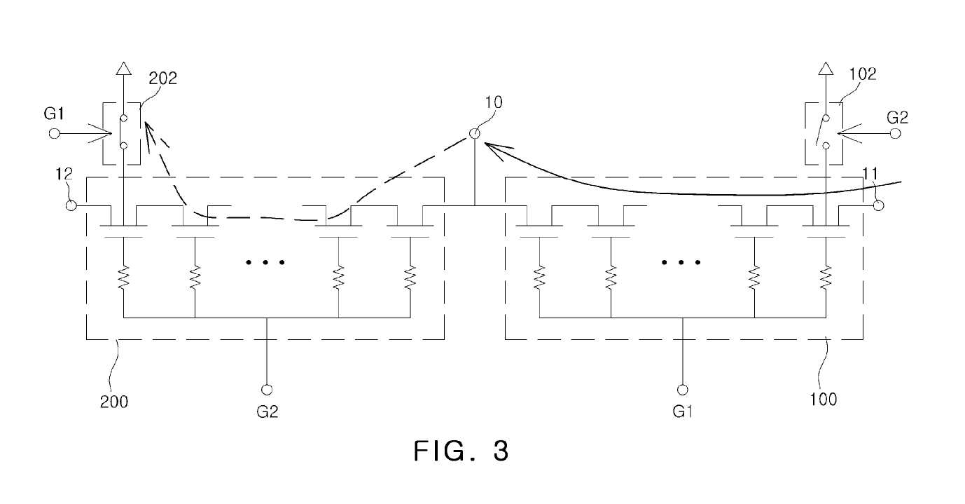

Next, an operation of the RF switch according to an exemplary embodiment of the present disclosure will be described in detail with reference to FIG. 3.

FIG. 3 is a view describing an operation of the RF switch according to an exemplary embodiment of the present disclosure.

Referring to FIG. 3, in the RF switch according to an exemplary embodiment of the present disclosure, the third switching device 102 may have one end coupled to a body of a first switching device disposed closely to the first port 11 among the plurality of first switching devices and the other end coupled to the first ground terminal.

Likewise, the fourth switching device 202 may have one end coupled to a body of a second switching device disposed closely to the second port 12 among the plurality of second switching devices and the other end coupled to the second ground terminal.

First, the case in which the first switching unit 100 is conducted by the first gate signal G1 will be described. In this case, all of the plurality of first switching devices included in the first switching unit 100 may be turned on to transfer signals from the first port 11 to the common port 10. In addition, the second switching unit 200 may receive the second gate signal G2 to block the signal transfer path between the common port 10 and the second port 12.

However, as described above as problems according to the related art, a size of the switching device is large, such that a signal from the first port 11 to the common port 10 may be output to the second port 12 through the second switching unit 200 due to a parasitic capacitance component coupled to a control terminal.

Therefore, in the RF switch according to an exemplary embodiment of the present disclosure, in the case in which the first switching unit 100 is conducted by the first gate signal G1, the fourth switching device 202 may also receive the first gate signal G1 to conduct between a body of a second switching device close to the second port 12 included in the second switching unit 200 and the second ground terminal. Therefore, the signal provided from the first port 11 to the common port 10 may be conducted to the second ground terminal before being output to the second port 12, whereby isolation characteristics may be improved.

Although not illustrated in the accompanying drawings, in the same principle, in the case in which the second switching unit 200 receives the second gate signal G2 to thereby be conducted, the third switching device 102 may also receive the second gate signal G2 to thereby be turned on. That is, a signal transfer path between a body of a first switching device close to the first port 11 included in the second switching unit 100 and the first ground terminal may be conducted by a switching operation of the third switching device 102, thereby preventing a signal from the second port 12 to the common port 10 from being output to the first port 11.

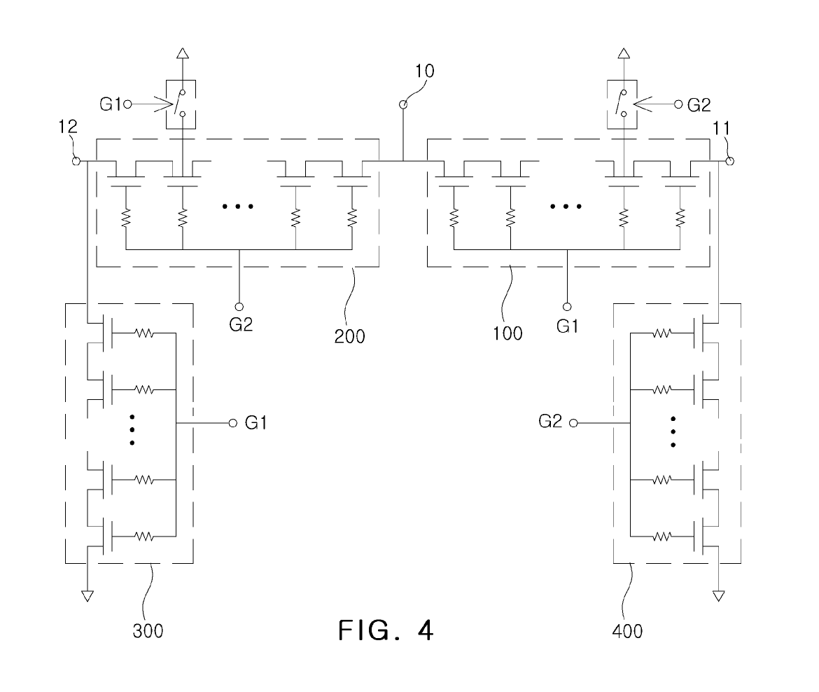

FIG. 4 is a circuit diagram of the RF switch of FIG. 2 having shunting units 300 and 400 added thereto.

Referring to FIG. 4, the RF switch according to an exemplary embodiment of the present disclosure may further include a first shunting unit 300 and a second shunting unit 400.

The first shunting unit 300 may be coupled between the second port 12 and the second switching unit 200 to open or block a signal transfer path between the second port 12 and a ground. Here, the first shunting unit 300 may include a plurality of first switching devices coupled to each other in series, wherein each of the plurality of first switching devices may receive the first gate signal G1 provided to a control terminal thereof to perform a switching operation.

The second shunting unit 400 may be coupled between the first port 11 and the first switching unit 100 to open or block a signal transfer path between the first port 11 and a ground. Here, the second shunting unit 400 may include a plurality of first switching devices coupled to each other in series, wherein each of the plurality of first switching devices may receive the second gate signal G2 provided to a control terminal thereof to perform a switching operation.

Meanwhile, each of the first switching devices and the second switching devices included in the first switching unit 100 and the second switching unit 200 may be a field effect transistor (FET) or a bipolar junction transistor (BJT).

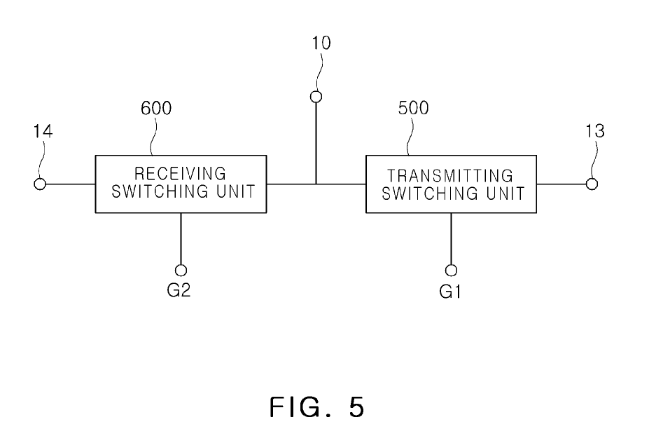

FIG. 5 is a block diagram illustrating an RF switch according to another exemplary embodiment of the present disclosure.

Referring to FIG. 5, an RF switch according to another exemplary embodiment of the present disclosure may include a transmitting switching unit 500 and a receiving switching unit 600.

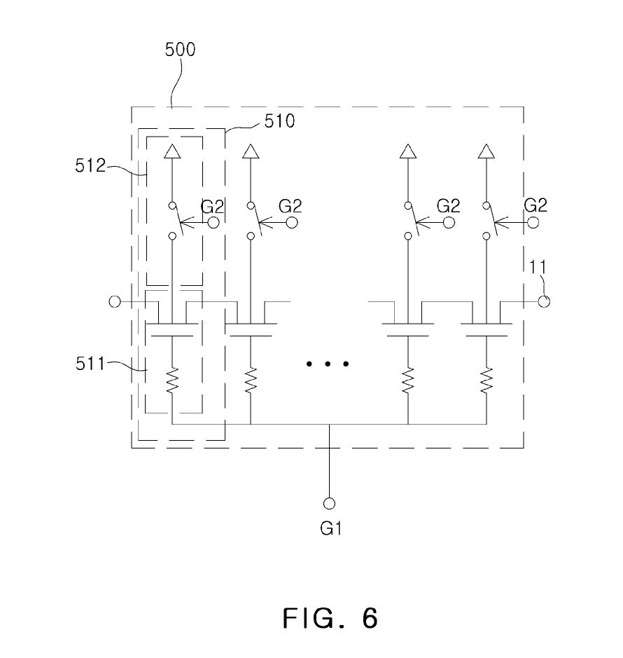

The transmitting switching unit 500 may be coupled between a common port 10 and a transmitting port 13 and may open or block a signal transfer path between the common port 10 and the transmitting port 13. Meanwhile, the transmitting switching unit 500 may include a plurality of first switch circuit units having first switching devices (See FIG. 6), respectively.

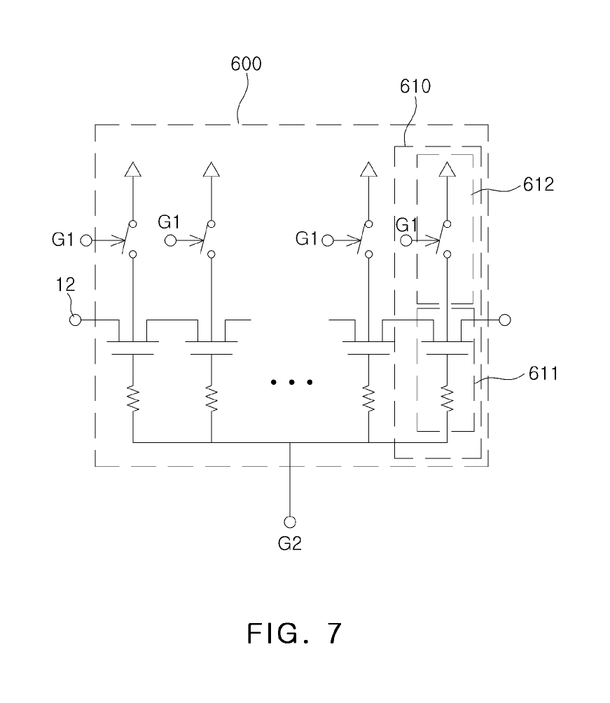

The receiving switching unit 600 may be coupled between the common port 10 and a receiving port 14 and may open or block a signal transfer path between the common port 10 and the receiving port 14. Meanwhile, the receiving switching unit 600 may include a plurality of second switch circuit units having second switching devices (See FIG. 7), respectively.

FIG. 6 is a circuit diagram illustrating a transmitting switching unit 500 in a configuration of the RF switch of FIG. 5 in more detail.

Referring to FIG. 6, the transmitting switching unit 500 in the configuration of the RF switch according to another exemplary embodiment of the present disclosure may include a plurality of first switch circuit units having first isolation units coupled in series with first switching devices, respectively, wherein the plurality of first switch circuit units may be coupled to each other in series.

A first switch circuit unit 510 having one first switching device 511 and a first isolation unit 512 coupled thereto will be described by way of example with reference to FIG. 6. The first isolation unit 512 may be coupled between a body of the first switching device 511 and a ground.

Here, one first switching device 511 may receive a first gate signal G1 applied to a control terminal thereof to perform a switching operation. In addition, the first isolation unit 512 may receive a second gate signal G2 applied thereto to perform a switching operation, thereby opening or blocking a signal transfer path between the body of the first switching device 511 and the ground.

Meanwhile, the transmitting switching unit 500 may include a plurality of first switch circuit units 510, wherein the plurality of first switch circuit units 510 may be coupled to each other in series. In addition, the first gate signal G1 and the second gate signal G2 may be complementary signals.

FIG. 7 is a circuit diagram illustrating a receiving switching unit 600 in a configuration of the RF switch of FIG. 5 in more detail.

Referring to FIG. 7, the receiving switching unit 600 in the configuration of the RF switch according to another exemplary embodiment of the present disclosure may include a plurality of second switch circuit units having second isolation units coupled in series with second switching devices, respectively, wherein the plurality of second switch circuit units may be coupled to each other in series.

A second switch circuit unit 610 having one second switching device 611 and a second isolation unit 612 coupled thereto will be described by way of example with reference to FIG. 7. The second isolation unit 612 may be coupled between a body of the second switching device 611 and a ground. Here, one second switching device 611 may receive a second gate signal G2 applied to a control terminal thereof to perform a switching operation. In addition, the second isolation unit 612 may receive a first gate signal G1 applied thereto to perform a switching operation, thereby opening or blocking a signal transfer path between the body of the second switching device 611 and the ground.

Meanwhile, the receiving switching unit 600 may include a plurality of second switch circuit units 610, wherein the plurality of second switch circuit units 610 may be coupled to each other in series. In addition, the first gate signal G1 and the second gate signal G2 may be complementary signals.

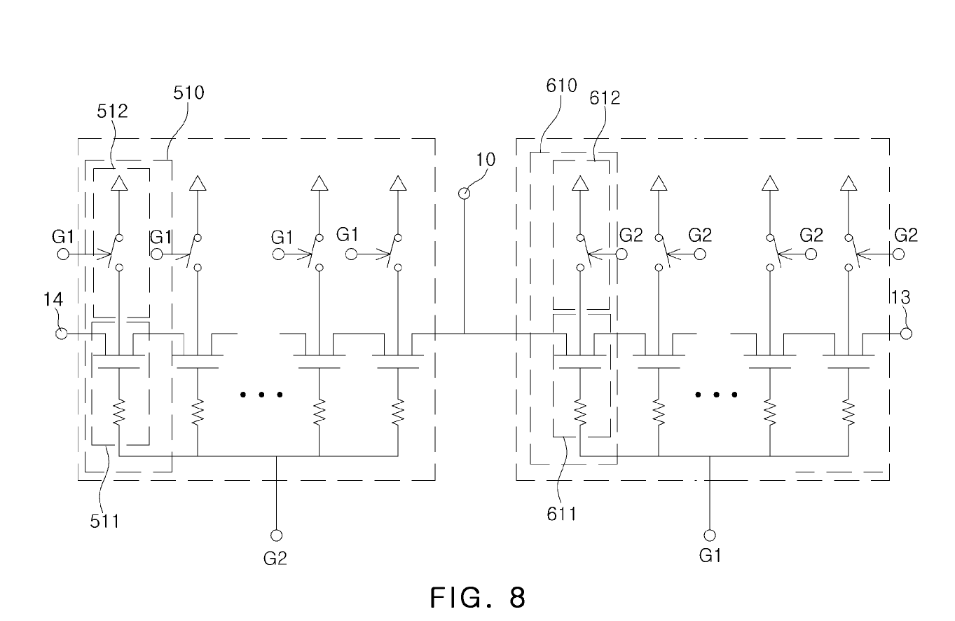

FIG. 8 is a circuit diagram illustrating the RF switch of FIG. 5 in more detail.

Referring to FIG. 8, the transmitting switching unit 500 may receive the first gate signal G1 applied to the control terminal of the first switching device included in each of the plurality of first switch circuit units to open or block a signal transfer path between the common port 10 and the transmitting port 13.

The receiving switching unit 600 may receive the second gate signal G2 applied to the control terminal of the second switching device included in each of the plurality of second switch circuit units to open or block a signal transfer path between the common port 10 and the receiving port 14.

Meanwhile, each of the first isolation units included in the plurality of first switch circuit units may receive the second gate signal G2 applied thereto to open or block a signal transfer path between the ground and the body of each of the first switching devices.

In addition, each of the second isolation units included in the plurality of second switch circuit units may receive the first gate signal G1 applied thereto to open or block a signal transfer path between the ground and the body of each of the second switching devices.

That is, in the RF switch according to another exemplary embodiment of the present disclosure, in the case in which the transmitting switching unit 500 is conducted by the first gate signal G1, the plurality of second isolation units included in the receiving switching unit 600 may receive the first gate signal G1 to conduct the signal transfer paths between the bodies of the second switching devices and the ground, thereby preventing a signal provided from the transmitting port 13 to the common port 10 from being output to the receiving port 14.

In addition, in the RF switch according to another exemplary embodiment of the present disclosure, in the case in which the receiving switching unit 600 is conducted by the second gate signal G2, the plurality of first isolation units included in the transmitting switching unit 500 may receive the second gate signal G2 to conduct the signal transfer paths between the bodies of the first switching devices and the ground, thereby preventing a signal provided from the receiving port 14 to the common port 10 from being output to the transmitting port 13.

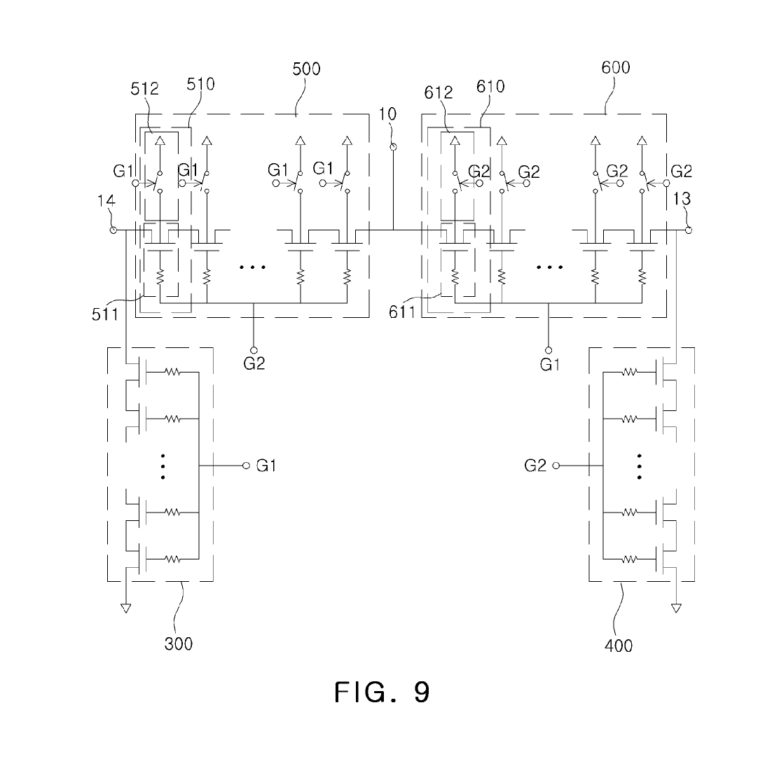

FIG. 9 is a circuit diagram of the RF switch of FIG. 7 having shunting units 300 and 400 added thereto.

The first shunting unit 300 may be coupled between the receiving port 14 and the receiving switching unit 600 to open or block a signal transfer path between the receiving port 14 and a ground. Here, the first shunting unit 300 may include a plurality of first switching devices coupled to each other in series, wherein each of the plurality of first switching devices may receive the first gate signal G1 provided to a control terminal thereof to perform a switching operation.

The second shunting unit 400 may be coupled between the transmitting port 13 and the transmitting switching unit 500 to open or block a signal transfer path between the transmitting port 13 and a ground. Here, the second shunting unit 400 may include a plurality of first switching devices coupled to each other in series, wherein each of the plurality of first switching devices may receive the second gate signal G2 provided to a control terminal thereof to perform a switching operation.

Meanwhile, each of the first switching devices and the second switching devices included in the first switching unit 100 and the second switching unit 200 may be an FET or a BJT.

As set forth above, with the RF switch according to exemplary embodiments of the present disclosure, the body terminal of at least one of the plurality of switching devices may be coupled to the ground terminal, whereby isolation characteristics may be improved and a parasitic capacitance component may be decreased.

While exemplary embodiments have been shown and described above, it will be apparent to those skilled in the art that modifications and variations could be made without departing from the spirit and scope of the present disclosure as defined by the appended claims.

What is claimed is:

1. An RF (Radio Frequency) switch comprising:
a common port transmitting and receiving a high frequency signal;
a first switching unit including a plurality of first switching devices coupled to each other in series and opening or blocking a signal transfer path between a first port to and from which the high frequency signal is input and output and the common port; and
a second switching unit including a plurality of second switching devices coupled to each other in series and opening or blocking a signal transfer path between a second port to and from which the high frequency signal is input and output and the common port,
wherein the first switching unit further includes a third switching device having one end coupled to a body of one of the plurality of first switching devices and the other end coupled to a first ground terminal, and the second switching unit further includes a fourth switching device having one end coupled to a body of one of the plurality of second switching devices and the other end coupled to a second ground terminal.

2. The RF switch of claim 1, wherein the third switching device conducts or blocks a signal transfer path between the first ground terminal and the body of one of the plurality of first switching devices when the plurality of second switching devices open or block the signal transfer path between the second port and the common port, and
the fourth switching device conducts or blocks a signal transfer path between the second ground terminal and the body of one of the plurality of second switching devices when the plurality of first switching devices open or block the signal transfer path between the first port and the common port.

3. The RF switch of claim 1, wherein the third switching device has one end coupled to a body of a first switching device disposed closely to the first port among the plurality of first switching devices and the other end coupled to the first ground terminal, and
the fourth switching device has one end coupled to a body of a second switching device disposed closely to the second port among the plurality of second switching devices and the other end coupled to the second ground terminal.

4. The RF switch of claim 1, wherein each of the plurality of first switching devices and the fourth switching device receive a first gate signal applied to a control terminal thereof to perform a switching operation, and each of the plurality of second switching devices and the third switching device receive a second gate signal applied to a control terminal thereof to perform a switching operation.

5. The RF switch of claim 1, further comprising:
a first shunting unit coupled between the second port and the second switching unit to open or block a signal transfer path between the second port and a ground; and
a second shunting unit coupled between the first port and the first switching unit to open or block a signal transfer path between the first port and a ground,
wherein the first shunting unit includes a plurality of first switching devices coupled to each other in series, and the second shunting unit includes a plurality of second switching devices coupled to each other in series.

6. The RF switch of claim 1, wherein each of the first switching devices and the second switching devices is a field effect transistor (FET) or a bipolar junction transistor (BJT).

7. An RF switch comprising:
a transmitting switching unit including a plurality of first switch circuit units having first switching devices, respectively, and coupled to each other in series; and
a receiving switching unit including a plurality of second switch circuit units having second switching devices, respectively, and coupled to each other in series,
wherein each of the plurality of first switch circuit units further includes a first isolation unit including a third switching device having one end coupled to a body of the first switching device and the other end coupled to a ground, and each of the plurality of second switch circuit units further includes a second isolation unit including a fourth switching device having one end coupled to a body of the second switching device and the other end coupled to a ground.

8. The RF switch of claim 7, wherein the transmitting switching unit receives a first gate signal applied to a control terminal of the first switching device included in each of the plurality of first switch circuit units to open or block a signal transfer path between a common port and a transmitting port, and
the receiving switching unit receives a second gate signal applied to a control terminal of the second switching device included in each of the plurality of second switch circuit units to open or block a signal transfer path between the common port and a receiving port.

9. The RF switch of claim 8, wherein each of the first isolation units included in the plurality of first switch circuit units receives the second gate signal applied thereto to open or block a signal transfer path between the ground and the body of each of the first switching devices, and
each of the second isolation units included in the plurality of second switch circuit units receives the first gate signal applied thereto to open or block a signal transfer path between the ground and the body of each of the second switching devices.

10. The RF switch of claim 7, wherein each of the first switching devices and the second switching devices is an FET or a BJT.

11. The RF switch of claim 7, further comprising:
a first shunting unit coupled between the receiving port and the receiving switching unit to open or block a signal transfer path between the receiving port and a ground; and
a second shunting unit coupled between the transmitting port and the transmitting switching unit to open or block a signal transfer path between the transmitting port and a ground,
wherein the first shunting unit includes a plurality of first switching devices coupled to each other in series, and the second shunting unit includes a plurality of second switching devices coupled to each other in series.
